(19) United States
(12) Patent Application Publication
(10) Pub. No.: US 2022/0322563 A1
(43) Pub. Date: Oct. 6, 2022

(54) BATTERY WITH BOOST PERFORMANCE UNDER LOW TEMPERATURES

(71) Applicant: DELL PRODUCTS, LP, Round Rock, TX (US)

(72) Inventors: Xizhi Cui, Shanghai (CN); Haijin Zhang, Shanghai (CN)

(21) Appl. No.: 17/326,925

(22) Filed: May 21, 2021

(30) Foreign Application Priority Data
Apr. 1, 2021 (CN) 202110357726.0

(51) Int. Cl. H05K 7/20; H05B 1/02

(52) U.S. Cl. CPC H05K 7/2039; H05B 1/0202; H05B 1/0252

(57) ABSTRACT

An information handling system includes a battery, a first temperature sensor, an electric heater, and a processor. The battery provides power to one or more other components of the information handling system. The first temperature sensor measures a temperature within the information handling system. The electric heater receives a current, and provides heat to the battery based on the reception of the current. The processor determines if the battery is in an idle or charging state. In response to the battery being in the idle state or the charging state, the processor receives an ambient temperature of the information handling system from the first temperature sensor. The processor determines whether the ambient temperature is below a first threshold temperature. In response to the ambient temperature being below the first threshold temperature, the processor provides the current to the electric heater to heat the battery.

### FIELD OF THE DISCLOSURE

The present disclosure generally relates to information handling systems, and more particularly relates to a battery with boost performance under low temperatures.

### BACKGROUND

As the value and use of information continues to increase, individuals and businesses seek additional ways to process and store information. One option is an information handling system. An information handling system generally processes, compiles, stores, or communicates information or data for business, personal, or other purposes. Technology and information handling needs, and requirements can vary between different applications. Thus, information handling systems can also vary regarding what information is handled, how the information is handled, how much information is processed, stored, or communicated, and how quickly and efficiently the information can be processed, stored, or communicated. The variations in information handling systems allow information handling systems to be general or configured for a specific user or specific use such as financial transaction processing, airline reservations, enterprise data storage, or global communications. In addition, information handling systems can include a variety of hardware and software resources that can be configured to process, store, and communicate information and can include one or more computer systems, graphics interface systems, data storage systems, networking systems, and mobile communication systems. Information handling systems can also implement various virtualized architectures. Data and voice communications among information handling systems may be via networks that are wired, wireless, or some combination.

### SUMMARY

An information handling system includes a battery, a first temperature sensor, an electric heater, and a processor. The battery may provide power to one or more other components of the information handling system. The first temperature sensor may measure a temperature within the information handling system. The electric heater may receive a current, and provide heat to the battery based on the reception of the current. The processor may determine if the battery is in an idle or charging state. In response to the battery being in the idle state or the charging state, the processor may receive an ambient temperature of the information handling system from the first temperature sensor. The processor may determine whether the ambient temperature is below a first threshold temperature. In response to the ambient temperature being below the first threshold temperature, the processor may provide the current to the electric heater to heat the battery.

### BRIEF DESCRIPTION OF THE DRAWINGS

It will be appreciated that for simplicity and clarity of illustration, elements illustrated in the Figures are not necessarily drawn to scale. For example, the dimensions of some elements may be exaggerated relative to other elements. Embodiments incorporating teachings of the present disclosure are shown and described with respect to the drawings herein, in which:

FIG. 1 is a block diagram of a general information handling system according to at least one embodiment of the present disclosure;

FIG. 2 is a block diagram of a portion of an information handling system according to at least one embodiment of the disclosure;

FIG. 3 is a diagram illustrating a cross section of a battery pack according to at least one embodiment of the disclosure; and

FIG. 4 is a flow diagram of a method for boosting the performance of a battery under low ambient temperatures according to at least one embodiment of the present disclosure.

The use of the same reference symbols in different drawings indicates similar or identical items.

### DETAILED DESCRIPTION OF THE DRAWINGS

The following description in combination with the Figures is provided to assist in understanding the teachings disclosed herein. The description is focused on specific implementations and embodiments of the teachings and is provided to assist in describing the teachings. This focus should not be interpreted as a limitation on the scope or applicability of the teachings.

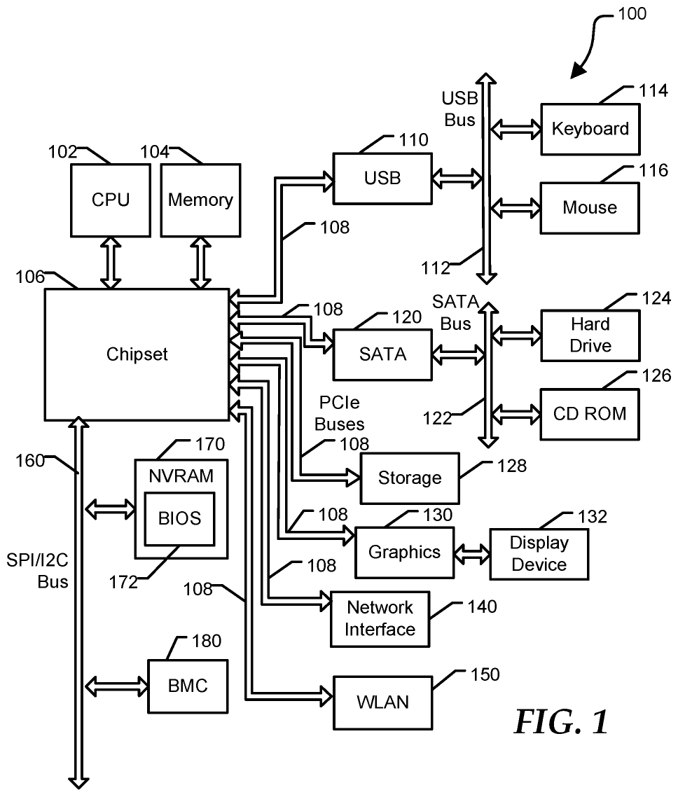

FIG. 1 illustrates a general information handling system 100. For purposes of this disclosure, an information handling system may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, an information handling system may be a personal computer, a PDA, a consumer electronic device, a network server or storage device, a switch router or other network communication device, or any other suitable device and may vary in size, shape, performance, functionality, and price. The information handling system may include memory, one or more processing resources such as a central processing unit (CPU) or hardware or software control logic. Additional components of the information handling system may include one or more storage devices, one or more communications ports for communicating with external devices as well as various other I/O devices, such as a keyboard, a mouse, and a video display. The information handling system may also include one or more busses operable to transmit communications between the various hardware components.

FIG. 1 illustrates a general information handling system 100. For purposes of this disclosure, an information handling system may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, an information handling system may be a personal computer, a PDA, a consumer electronic device, a network server or storage device, a switch router or other network communication device, or any other suitable device and may vary in size, shape, performance, functionality, and price. The information handling system may include memory, one or more processing resources such as a central processing unit (CPU) or hardware or software control logic. Additional components of the information handling system may include one or more storage devices, one or more communications ports for communicating with external devices as well as various other I/O devices, such as a keyboard, a mouse, and a video display. The information handling system may also include one or more busses operable to transmit communications between the various hardware components.

Information handling system 100 including a processor 102, a memory 104, a chipset 106, one or more PCIe buses 108, a universal serial bus (USB) controller 110, a USB bus 112, a keyboard device controller 114, a mouse device controller 116, a configuration a SATA bus controller 120, a SATA bus 122, a hard drive device controller 124, a compact disk read only memory (CD ROM) device controller 126, a storage 128, a graphics device controller 130, a network interface controller (NIC) 140, a wireless local area network (WLAN) or wireless wide area network (WWAN) controller 150, a serial peripheral interface (SPI) bus 160, a NVRAM 170 for storing BIOS 172, and a baseboard management controller (BMC) 180. In an example, chipset 106 may be directly connected to an individual end point via a PCIe root port within the chipset and a point-to-point topology as shown in FIG. 1. BMC 180 can be referred to as a service processor or embedded controller (EC). Capabilities and functions provided by BMC 180 can vary considerably based on the type of information handling system. For example, the term baseboard management system is often used to describe an embedded processor included at a server, while an embedded controller is more likely to be found in a consumer-level device. As disclosed herein, BMC 180 represents a processing device different from CPU 102, which provides various management functions for information handling system 100. For example, an embedded controller may be responsible for power management, cooling management, and the like. An embedded controller included at a data storage system can be referred to as a storage enclosure processor.

System 100 can include additional processors that are configured to provide localized or specific control functions, such as a battery management controller. Bus 160 can include one or more busses, including a SPI bus, an I2C bus, a system management bus (SMBUS), a power management bus (PMBUS), and the like. BMC 180 can be configured to provide out-of-band access to devices at information handling system 100. As used herein, out-of-band access herein refers to operations performed prior to execution of BIOS 172 by processor 102 to initialize operation of system 100.

BIOS 172 can be referred to as a firmware image, and the term BIOS is herein used interchangeably with the term firmware image, or simply firmware. BIOS 172 includes instructions executable by CPU 102 to initialize and test the hardware components of system 100, and to load a boot loader or an operating system (OS) from a mass storage device. BIOS 172 additionally provides an abstraction layer for the hardware, such as a consistent way for application programs and operating systems to interact with the keyboard, display, and other input/output devices. When power is first applied to information handling system 100, the system begins a sequence of initialization procedures. During the initialization sequence, also referred to as a boot sequence, components of system 100 are configured and enabled for operation, and device drivers can be installed. Device drivers provide an interface through which other components of the system 100 can communicate with a corresponding device.

Information handling system 100 can include additional components and additional busses, not shown for clarity. For example, system 100 can include multiple processor cores, audio devices, and the like. While a particular arrangement of bus technologies and interconnections is illustrated for the purpose of example, one of skill will appreciate that the techniques disclosed herein are applicable to other system architectures. System 100 can include multiple CPUs and redundant bus controllers. One or more components can be integrated together. For example, portions of chipset 106 can be integrated within CPU 102. Additional components of information handling system 100 can include one or more storage devices that can store machine-executable code, one or more communications ports for communicating with external devices, and various input and output (I/O) devices, such as a keyboard, a mouse, and a video display. An example of information handling system 100 includes a multi-tenant chassis system where groups of tenants (users) share a common chassis, and each of the tenants has a unique set of resources assigned to them. The resources can include blade servers of the chassis, input/output (I/O) modules, Peripheral Component Interconnect-Express (PCIe) cards, storage controllers, and the like.

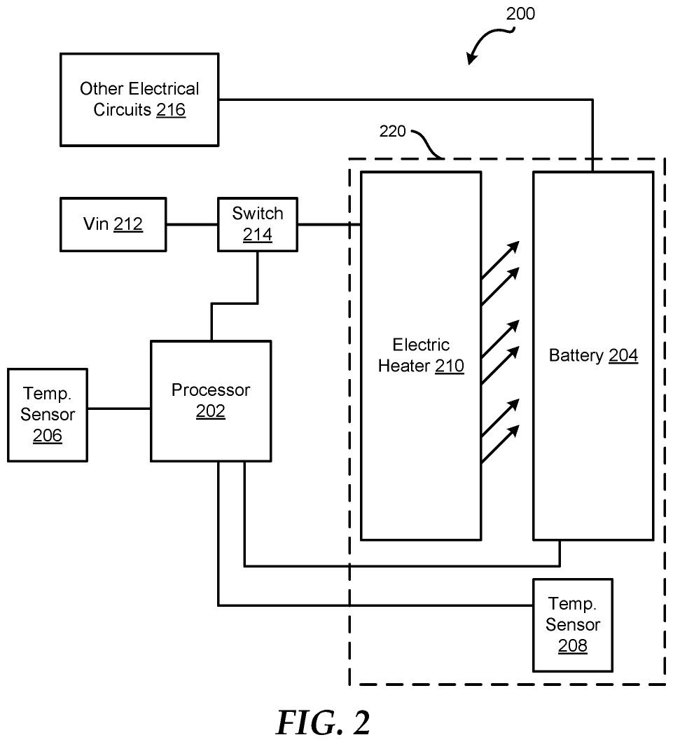

In an example, information handling system 100 may include any suitable device including, but not limited to, device assembly 200 of FIG. 2. Information handling system 100 can include a set of instructions that can be executed to cause the information handling system to perform any one or more of the methods or computer based functions disclosed herein. The information handling system 100 may operate as a standalone device or may be connected to other computer systems or peripheral devices, such as by a network.

In a networked deployment, the information handling system 100 may operate in the capacity of a server or as a client user computer in a server-client user network environment, or as a peer computer system in a peer-to-peer (or distributed) network environment. The information handling system 100 can also be implemented as or incorporated into various devices, such as a personal computer (PC), a tablet PC, a set-top box (STB), a personal digital assistant (PDA), a mobile device, a palmtop computer, a laptop computer, a desktop computer, a communications device, a wireless telephone, a land-line telephone, a control system, a camera, a scanner, a facsimile machine, a printer, a pager, a personal trusted device, a web appliance, a network router, switch or bridge, or any other machine capable of executing a set of instructions (sequential or otherwise) that specify actions to be taken by that machine. In a particular embodiment, the computer system 100 can be implemented using electronic devices that provide voice, video, or data communication. Further, while a single information handling system 100 is illustrated, the term “system” shall also be taken to include any collection of systems or sub-systems that individually or jointly execute a set, or multiple sets, of instructions to perform one or more computer functions.

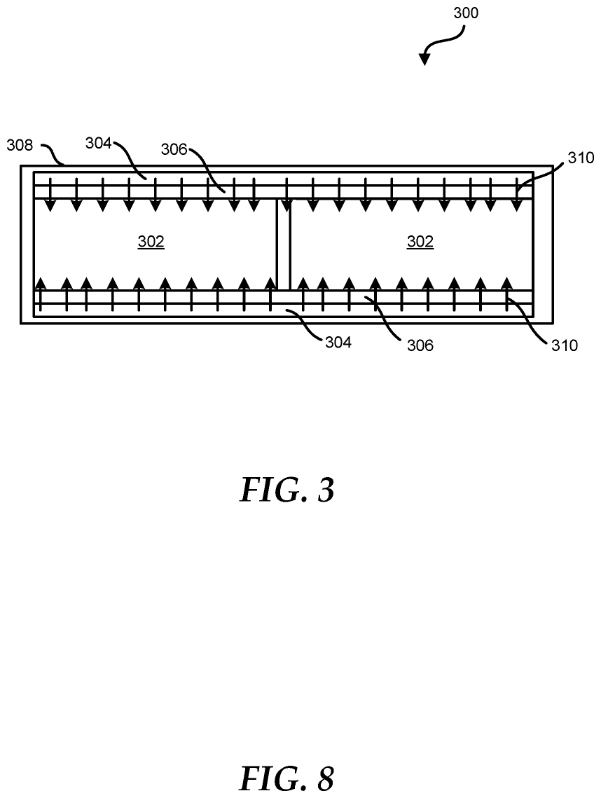

FIG. 2 illustrates of a portion of an information handling system 200 according to at least one embodiment of the disclosure. In an example, information handling system 201 may be any suitable information handling system including, but not limited to, such as information handling system 100 of FIG. 1. Information handling system 200 includes a processor 202, a battery 204, temperature sensors 206 and 208, an electric heater 210, an input voltage 212, a switch 214, and other electrical circuits 216. Battery 204, temperature sensor 208, and electric heater 210 may be incorporated into a single battery pack 220 as will be described with respect to FIG. 3 below. In certain examples, information handling system 200 may include additional components over those shown in FIG. 2 without varying from the scope of this disclosure.

In an example, battery 204 may be any suitable type of battery including, but not limited to, a rechargeable battery utilized as a backup power source for components in an information handling system. For example, battery 204 may be a lithium-ion battery. The backup power from battery 204 may ensure a high reliability of storage systems and prevent data unavailability/data loss (DU/DL) events in information handling system 200. In an example, electric heater 210 may be any suitable type of heater including, but not limited to, a polyimide film electric heater. In certain examples, electric heater 210 may be made from any material that may be easily curled around battery 204. For example, polyimide film material may have excellent insulation strength, heat transfer efficiency, flame resistance, and may be easily curled.

In an example, information handling system 200 may have different ambient temperatures based on the use and components of the information handling system. For example, other electrical circuits 216 may include memory drives, such as M.2 drives and solid state drives (SSD) drives, and the ambient temperature may be set to provide cooling and heat dissipation to the memory drives. In an example, the ambient temperature may be any suitable temperature including, but not limited to, anywhere from five to forty-five degrees Celsius. In certain examples, battery 204 may have a substantially lower performance level when the ambient temperature is below a threshold temperature. For example, usable discharge energy of battery 204 may downgrade from a maximum level to a much lower level when the battery is at low temperatures.

In certain examples, a charging current battery 204 must be limited, such as less than half an ampere, so that the lifetime of the battery is not impacted. Charging with a small charge current may result in a longer time to charge battery 204 back to full capacity. Information handling system 200 may implement back-to-back vaulting operations, which includes battery 204 to cache data in the memory drives of the information handling system. In current information handling systems, an OS boot time is not changed for different conditions of a battery, such that a longer time to charge the battery to a level that the battery may be able to support system vaulting under low temperature may be greater than the OS boot time. Charging battery 204 during periods of low ambient temperatures may also generate under-current warnings within information handling system 200. Processor 202 and electrical heater 210 may combine to improve performance of battery 204 and information handling system 200 even with low ambient temperatures.

During operation, information handling system 200 may receive power from an AC power source, and the power may be provided to all of the components in the information handling system. While information handling system 200 is receiving power from the AC power source, processor 202 may determine whether battery 204 is in either a charging mode or an idle mode. In response to battery 204 being in the charging mode or the idle mode, processor 202 may receive an ambient temperature reading from temperature sensor 206.

In response to receiving the ambient temperature, processor 202 may perform one or more suitable operations. For example, processor 202 may determine whether the ambient temperature is less than a first threshold temperature. In an example, the first threshold temperature may be any suitable temperature, such as a temperature at which battery 204 has a decrease in charge capacity as compare to a charge capacity of the battery at higher temperatures. For example, the first threshold temperature may be fifteen degrees Celsius or the like. In certain examples, when the ambient temperature is above the first threshold temperature, the usable power and energy level of the battery may be sufficient for a desired amount of backup power for the memory devices of the information handling system.

If processor 202 determines the ambient temperature is less than the first threshold temperature, one or more operations may be performed to activate electric heater 210 and generate heat to be provided to battery 204. For example, processor 202 may close switch 214, which in turn may provide an input voltage 212 to electric heater 210. In response to the reception of input voltage 212, electric heater 210 may provide an electrical current flow through one or more elements of the electric heater. As the electrical current flows through the one or more elements, electric heater 210 may produce heat. The heat is dissipated to battery 204, which in turn may warm up one or more battery cells of the battery.

While the heat is provided to battery 204, processor 202 may determine whether a battery temperature is less than a second threshold temperature. In an example, the second threshold temperature may be any suitable temperature, such as a temperature at which the battery has an increase in charge capacity as compared to temperatures below the first threshold temperature. For example, the second threshold temperature may be twenty degrees Celsius or the like. In an example, processor 202 may receive the battery temperature from temperature sensor 208. If the battery temperature is greater than the second threshold temperature, processor 202 may perform any suitable operation to turn off electric heater 210. For example, processor 202 may open switch 214 to turn off electric heater 210. In certain examples, after electric heater 210 is turned off, processor 202 may continue to receive the ambient temperature from temperature sensor 206 and the battery temperature from temperature sensor 208 at any suitable interval. For example, the interval may be any suitable amount of time including, but not limited to, one second and two seconds. In an example, the first threshold temperature may be less than the second threshold temperature to provide a hysteresis control factor, which may prevent processor 202 may repeatedly turning electric heater on and off as the temperature fluctuates.

In an example, the AC power source may fail or otherwise have a disruption in providing power to information handling system 200 while battery 204 is in a discharge mode. In this situation, processor 202 may perform one or more suitable operations to determine whether to heat battery 204 prior to the discharging of the battery. For example, processor 204 may receive the ambient temperature from temperature sensor 206 and the battery temperature from temperature sensor 208. Processor 202 may determine whether the battery temperature is below the second threshold temperature. If so, processor 202 may close switch 214 to provide input voltage 212 to electric heater 210. Battery 204 may quickly heat up based on a combination of the heat from electric heater 210 and the heat generated by the discharging of the battery. Processor 202 may turn off electric heater 210 when the battery temperature exceeds the second threshold temperature.

In certain examples, the first and second threshold temperatures may be set to any suitable temperatures and processor 202 may be adjust the threshold temperatures based on a request from the information handling system 200. In an example, the request to change the threshold temperatures may be from a user of information handling system 200 or may be calculated by one or more of the other components 216. Processor 202 and electrical heater 210 may combine to improve performance of battery 204 and information handling system 200 during periods of low ambient temperatures without consuming processing power of other components of the information handling system.

FIG. 3 illustrates a cross section of a battery pack 300 according to at least one embodiment of the disclosure. In an example, battery pack 300 may be any suitable battery, such as battery 204 of FIG. 2. Battery pack 300 includes one or more battery cells 302, an electric heater 304, a thermal pad 306, and a wrap 308. In an example, electric heater 304 may be any suitable heating element that provides heat when a voltage is applied to the electric heater. Thermal pad 306 may be any thermally conductive material capable of transferring heat from electric heater 304 to battery cells 302. Wrap 308 may be any suitable material, such as a shrink wrap material or the like.

In certain examples, electric heater 304 and thermal pad 306 may be wrapped around battery cells 302, and wrap 308 may hold or contain the battery cells, electric heater, and thermal pad together as a single component, such as battery pack 300. In an example, wrap 308 may be utilized to contain the heat from electric heater 304 within battery pack 300, such that the heat is transferred to battery cells 302. Thermal pad 306 may be placed in between and in physical communication with battery cells 302 and with electric heater 304. In an example, thermal pad 306 may evenly spread the heat from electric heater 304 to battery cells 302. Thermal pad 306 may also regulate or control the heat dissipation direction from electric heater 304 to battery cells 302 as shown by arrows 310.

In an example, a temperature sensor, such as temperature sensor 208 of FIG. 2, may be located in between battery cell 302 and thermal pad 306. In this example, the temperature sensor may detect accurate temperatures of battery cells 302. The temperature sensor may provide temperatures of battery cells 302 to a processor, such as processor 202 of FIG. 2, at periodic intervals.

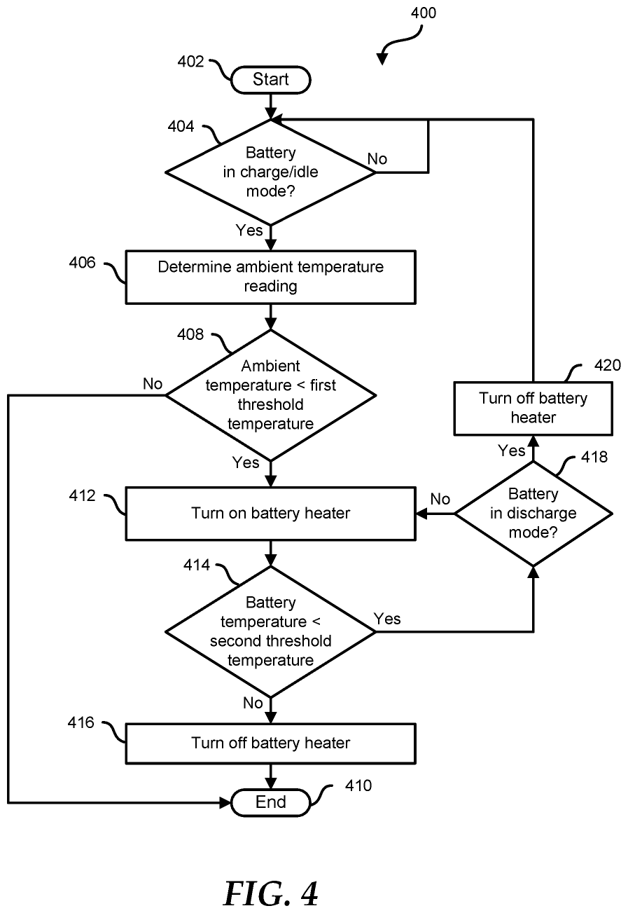

FIG. 4 illustrates a flow diagram of a method 400 for boosting the performance of a battery under low ambient temperatures according to at least one embodiment of the current disclosure, starting at block 402. It will be readily appreciated that not every method step set forth in this flow diagram is always necessary, and that certain steps of the methods may be combined, performed simultaneously, in a different order, or perhaps omitted, without varying from the scope of the disclosure. FIG. 4 may be employed in whole, or in part, by information handling system 100 depicted in FIG. 1, information handling system 200 depicted in FIG. 2, or any other type of system, controller, device, module, processor, or any combination thereof, operable to employ all, or portions of, the method of FIG. 4.

At block 404, a determination is made whether a battery is in either a charging mode or an idle mode. In an example, the battery may be any suitable type of battery including, but not limited to, a rechargeable battery utilized as a backup power source for components in an information handling system. For example, the battery may be a lithium-ion battery. The battery may provide power to enable the system to cache memories to memory drives, such as M.2 drives and SSD drives, during an AC power failure in the information handling system. The backup power from the battery may ensure a high reliability of storage systems and prevent data unavailability/data loss (DU/DL) events in the information handling system.

In response to the battery being in either the charging mode or the idle mode, an ambient temperature reading is determined at block 406. In an example, the ambient temperature may be any suitable temperature including, but not limited to, anywhere from five to forty-five degrees Celsius. In certain examples, the ambient temperature may be set for a working condition for the memory devices within the information handling system. The ambient may be utilized to cool the memory devices within information handling system.

At block 408, a determination is made whether the ambient temperature is less than a first threshold temperature. In an example, the threshold temperature may be any suitable temperature, such as a temperature at which the battery has a decrease in charge capacity if the temperature of the battery is below the first threshold temperature. For example, the first threshold temperature may be fifteen degrees Celsius or the like. If the ambient temperature is not less than the first threshold temperature, the flow ends at block 410. When the ambient temperature is above the first threshold temperature, the usable power and energy level of the battery may be sufficient for a desired amount of backup power for the memory devices of the information handling system.

If the ambient temperature is less than the first threshold temperature, an electric heater is turned on at block 412. In an example, the electric heater may be any suitable type of heater including, but not limited to, a polyimide film electric heater. In certain examples, the electric heater may be made from any material that may be easily curled around the battery. For example, polyimide film material may have excellent insulation strength, heat transfer efficiency, flame resistance, and may be easily curled.

At block 414, a determination is made whether the battery temperature is less than a second threshold temperature. In an example, the second threshold temperature may be any suitable temperature, such as a temperature at which the battery has an increase in charge capacity if the temperature of the battery is above the second threshold temperature. For example, the first threshold temperature may be twenty degrees Celsius or the like. If the battery temperature is not less than the second threshold temperature, the electric heater is turned off at block 416, and the method ends at block 410.

If the battery temperature is less than the second threshold temperature, a determination is made whether the battery is in a discharge mode at block 418. If the battery is not in the discharge mode, the method continues as state above at block 412. If the battery is in the discharge mode, the electric heater is turned off at block 420, and the method continues as stated above at block 404. In an example, while in the discharge mode, the battery may increase in temperature as power is provided to the other components of the information handling system, such that the heat from the electric heater is unnecessary to keep the battery at the desired temperature.

Referring back to FIG. 1, the information handling system 100 can include a disk drive unit and may include a computer-readable medium, not shown in FIG. 1, in which one or more sets of instructions, such as software, can be embedded. Further, the instructions may embody one or more of the methods or logic as described herein. In a particular embodiment, the instructions may reside completely, or at least partially, within system memory 104 or another memory included at system 100, and/or within the processor 102 during execution by the information handling system 100. The system memory 104 and the processor 102 also may include computer-readable media.

While the computer-readable medium is shown to be a single medium, the term “computer-readable medium” includes a single medium or multiple media, such as a centralized or distributed database, and/or associated caches and servers that store one or more sets of instructions. The term “computer-readable medium” shall also include any medium that is capable of storing, encoding, or carrying a set of instructions for execution by a processor or that cause a computer system to perform any one or more of the methods or operations disclosed herein.

In a particular non-limiting, exemplary embodiment, the computer-readable medium can include a solid-state memory such as a memory card or other package that houses one or more non-volatile read-only memories. Further, the computer-readable medium can be a random access memory or other volatile re-writable memory. Additionally, the computer-readable medium can include a magneto-optical or optical medium, such as a disk or tapes or other storage device to store information received via carrier wave signals such as a signal communicated over a transmission medium. Furthermore, a computer readable medium can store information received from distributed network resources such as from a cloud-based environment. A digital file attachment to an e-mail or other self-contained information archive or set of archives may be considered a distribution medium that is equivalent to a tangible storage medium. Accordingly, the disclosure is considered to include any one or more of a computer-readable medium or a distribution medium and other equivalents and successor media, in which data or instructions may be stored.

When referred to as a “device,” a “module,” or the like, the embodiments described herein can be configured as hardware. For example, a portion of an information handling system device may be hardware such as, for example, an integrated circuit (such as an Application Specific Integrated Circuit (ASIC), a Field Programmable Gate Array (FPGA), a structured ASIC, or a device embedded on a larger chip), a card (such as a Peripheral Component Interface (PCI) card, a PCI-express card, a Personal Computer Memory Card International Association (PCMCIA) card, or other such expansion card), or a system (such as a motherboard, a system-on-a-chip (SoC), or a stand-alone device).

The device or module can include software, including firmware embedded at a processor or software capable of operating a relevant environment of the information handling system. The device or module can also include a combination of the foregoing examples of hardware or software. Note that an information handling system can include an integrated circuit or a board-level product having portions thereof that can also be any combination of hardware and software.

Devices, modules, resources, or programs that are in communication with one another need not be in continuous communication with each other, unless expressly specified otherwise. In addition, devices, modules, resources, or programs that are in communication with one another can communicate directly or indirectly through one or more intermediaries.

Although only a few exemplary embodiments have been described in detail herein, those skilled in the art will readily appreciate that many modifications are possible in the exemplary embodiments without materially departing from the novel teachings and advantages of the embodiments of the present disclosure. Accordingly, all such modifications are intended to be included within the scope of the embodiments of the present disclosure as defined in the following claims. In the claims, means-plus-function clauses are intended to cover the structures described herein as performing the recited function and not only structural equivalents, but also equivalent structures.

What is claimed is:

1. An information handling system comprising:
a battery to provide power to one or more components of the information handling system;
a first temperature sensor to measure an ambient temperature within the information handling system;
an electric heater in thermal communication with the battery, the electric heater to receive a current, and to provide heat to the battery based on the reception of the current; and
a processor to communicate with the battery, with the first temperature sensor, and with the electric heater, the processor to:
determine if the battery is in an idle or a charging state;
in response to the battery being in the idle state or in the charging state, receive the ambient temperature of the information handling system from the first temperature sensor;
determine whether the ambient temperature is below a first threshold temperature; and
in response to the ambient temperature being below the first threshold temperature, provide the current to the electric heater to heat the battery.

2. The information handling system of claim 1, further comprising:
a thermal pad in physical communication with both the battery and the electric heater, the thermal to transfer the heat produced by the electric heater to the battery.

3. The information handling system of claim 1, further comprising:
a wrap in physical communication with the electric heater, the wrap to hold the electric heater in within a predetermined proximity to the battery.

4. The information handling system of claim 1, wherein while the electric heater is heating the battery, the processor further to:
receive a temperature of the battery;
determine whether the temperature of the battery is below a second threshold temperature; and
in response to the temperature of the battery being above the second threshold temperatures, turn off the electric heater.

5. The information handling system of claim 1, wherein while the electric heater is heating the battery, the processor further to:
receive a temperature of the battery;
determine whether the temperature of the battery is below a second threshold temperature;
in response to the temperature of the battery being below the second threshold temperatures, determine if the battery has transitioned to a discharge mode; and
in response to the battery has transitioned to the discharge mode, turn off the electric heater.

6. The information handling system of claim 5, further comprising:
a second temperature sensor in communication with the processor, the second temperature sensor to detect the temperature of the battery.

7. The information handling system of claim 6, wherein the processor further to receive the temperature of the battery from the second temperature sensor at a periodic intervals.

8. The information handling system of claim 1, wherein the one or more other components includes a solid state drive.

9. A method comprising:
determining, by a processor of an information handling system, if a battery of the information handling system is in an idle or charging state;
in response to the battery being in the idle state or the charging state, receiving an ambient temperature of the information handling system from a first temperature sensor of the information handling system;
determining whether the ambient temperature is below a first threshold temperature; and
in response to the ambient temperature being below the first threshold temperature, providing a current to an electric heater to heat the battery.

10. The method of claim 9, wherein while the electric heater is heating the battery, the method further comprising:
receiving a temperature of the battery;
determining whether the temperature of the battery is below a second threshold temperature; and
in response to the temperature of the battery being above the second threshold temperatures, turning off the electric heater.

11. The method of claim 9, wherein while the electric heater is heating the battery, the method further comprising:
receive a temperature of the battery;
determine whether the temperature of the battery is below a second threshold temperature;
in response to the temperature of the battery being below the second threshold temperatures, determine if the battery has transitioned to a discharge mode; and
in response to the battery has transitioned to the discharge mode, turn off the electric heater.

12. The method of claim 11, wherein the temperature of the battery is received from a second temperature sensor of the information handling system.

13. The method of claim 12, further comprising:
receiving the temperature of the battery from the second temperature sensor at periodic intervals.

14. The method of claim 9, further comprising:
transferring, by a thermal pad, the heat produced by the electric heater to the battery.

15. The method of claim 9, wherein the one or more other components includes a solid state drive.

16. An information handling system comprising:
a temperature sensor to measure an ambient temperature within the information handling system;
a battery pack including:
an electric heater in thermal communication with a battery, the electric heater to receive a current, and to provide heat to the battery based on the reception of the current;
a thermal pad in physical communication with both the battery and the electric heater, the thermal to transfer the heat produced by the electric heater to the battery; and
a wrap in physical communication with the electric heater, the wrap to hold the electric heater within a predetermined proximity to the battery; and
a processor to:
if the battery is in an idle state or a charging state, then receive the ambient temperature of the information handling system from the temperature sensor; and
if the ambient temperature is below a first threshold temperature, then provide the current to the electric heater to heat the battery.

17. The information handling system of claim 16, wherein while the electric heater is heating the battery, the processor further to:
receive a temperature of the battery;
determine whether the temperature of the battery is below a second threshold temperature; and
in response to the temperature of the battery being above the second threshold temperatures, turn off the electric heater.

18. The information handling system of claim 16, wherein while the electric heater is heating the battery, the processor further to:
receive a temperature of the battery;
determine whether the temperature of the battery is below a second threshold temperature;
in response to the temperature of the battery being below the second threshold temperatures, determine if the battery has transitioned to a discharge mode; and
in response to the battery has transitioned to the discharge mode, turn off the electric heater.

19. The information handling system of claim 16, wherein the processor further to receive the temperature of the battery at periodic intervals.

20. The information handling system of claim 16, wherein the battery provides power to a solid state drive.
